(19) United States
(12) Patent Application Publication
(10) Pub. No.: US 2016/0025822 A1
(43) Pub. Date: Jan. 28, 2016

(54) GAS CELL AND MAGNETIC MEASURING APPARATUS

(71) Applicant: SEIKO EPSON CORPORATION, Tokyo (JP)

(72) Inventor: Satoshi TAKAHASHI, Komae-shi (JP)

(21) Appl. No.: 14/805,895

(22) Filed: Jul. 22, 2015

(30) Foreign Application Priority Data
Jul. 24, 2014 (JP) 2014-150717
May 19, 2015 (JP) 2015-101620

(51) Int. Cl. G01R 33/032

(52) U.S. Cl. CPC G01R 33/032

(57) ABSTRACT

A gas cell includes: a cell main body; a first wall portion defining an interior space serving as a main chamber in the cell main body; an auxiliary chamber storing an alkali metal; a second wall portion defining the auxiliary chamber connected with the main chamber in the cell main body; and a heater covering the first wall portion and vaporizing the alkali metal. The second wall portion is thicker than the first wall portion.

### BACKGROUND

1. Technical Field

The present invention relates to a gas cell and a magnetic measuring apparatus.

2. Related Art

Entering the aging era, the degree of importance of tests for circulatory disorders is increasing year by year. For example, as methods for measuring the condition of the heart, electrocardiographs or catheters are mainly in widespread use at present. However, the electrocardiograph detects also electric signals generated from the muscle of the surface layer of the body other than electric signals generated from the heart muscle, and thus has the problem of poor accuracy. The catheter has the problem of a very large burden on a test subject.

For coping with such a problem, a technique for obtaining information indicating the condition of the heart by measuring a magnetic field generated from the heart is known. For example, JP-A-2009-236599 and JP-A-2005-170298 disclose optically pumped magnetic measuring apparatuses.

As one method for increasing the sensitivity of optically pumped magnetic measuring apparatuses, increasing the atom density of an alkali metal gas to be enclosed in a cell can be mentioned. In this case, an auxiliary chamber in which an alkali metal solid is enclosed as a supply source of the alkali metal is provided in some cases. In this case, when the auxiliary chamber is heated, the alkali metal in the auxiliary chamber is liquefied and flows therefrom into the main chamber in some cases. When the alkali metal in the form of liquid flows into the main chamber, the measurement of the magnetic field is adversely affected. Moreover, when the alkali metal gas enclosed in the main chamber is solidified on the wall surface of the main chamber, the measurement is adversely affected similarly.

### SUMMARY

An advantage of some aspects of the invention is to provide a technique for suppressing the adhesion of an alkali metal in the form of liquid or solid to the wall surface of a main chamber.

An aspect of the invention provides a gas cell including: a first chamber having an interior space defined by a first surface of a first wall portion; a second chamber defined by a first surface of a second wall portion and connected with the first chamber; and a heater provided along a second surface of the first wall portion, the second surface being different from the first surface, wherein a distance between the first surface of the second wall portion and a second surface thereof different from the first surface is greater than a distance between the first and second surfaces of the first wall portion.

According to the gas cell, it is possible to suppress the adhesion of an alkali metal in the form of liquid or solid to the wall surface of the first chamber.

A heat capacity of the second wall portion may be greater than a heat capacity of the first wall portion.

The second wall portion may include a first portion formed of the same structure material as the first wall portion, and a second portion provided on at least a portion of an outer surface of the first portion and formed of a metal.

A ratio of a surface area of the first surface of the second wall portion to a volume of the second chamber may be greater than a ratio of a surface area of the first surface of the first wall portion to a volume of the first chamber.

Another aspect of the invention provides a gas cell including: a cell main body; a first wall portion defining an interior space serving as a main chamber in the cell main body; an auxiliary chamber storing an alkali metal; a second wall portion defining the auxiliary chamber connected with the main chamber in the cell main body; and a heater covering the first wall portion and vaporizing the alkali metal, wherein the second wall portion is thicker than the first wall portion.

According to the gas cell, it is possible to suppress the adhesion of the alkali metal in the form of liquid or solid to the wall surface of the main chamber.

A heat capacity of the second wall portion may be higher than a heat capacity of the first wall portion.

According to the gas cell with this configuration, compared to the case where the thermal conductivity of the second wall portion is equal to or less than the thermal conductivity of the first wall portion, it is possible to suppress the adhesion of the alkali metal in the form of liquid or solid to the wall surface of the main chamber.

The second wall portion may include a first portion formed of the same structure material as the first wall portion, and a second portion provided on at least a portion of an outer surface of the first portion and formed of a metal.

According to the gas cell with this configuration, the gas cell can be manufactured more simply.

A ratio of a surface area of the second wall portion to a volume of the auxiliary chamber may be greater than a ratio of a surface area of the first wall portion to a volume of the main chamber.

According to the gas cell with this configuration, compared to the case where the ratio of the surface area of the second wall portion to the volume of the auxiliary chamber is equal to or less than the ratio of the surface area of the first wall portion to the volume of the main chamber, it is possible to suppress the adhesion of the alkali metal in the form of liquid or solid to the wall surface of the main chamber.

Still another aspect of the invention provides a magnetic measuring apparatus including: any of the gas cells described above; a light source emitting light onto the gas cell; and a detector detecting the light passed through the gas cell, wherein the vaporized alkali metal changes the orientation of a polarization plane of the light in response to a magnetic field strength.

According to the magnetic measuring apparatus, it is possible to suppress the adhesion of the alkali metal in the form of liquid or solid to the wall surface of the main chamber.

### BRIEF DESCRIPTION OF THE DRAWINGS

The invention will be described with reference to the accompanying drawings, wherein like numbers reference like elements.

FIG. 1 is a diagram showing a configuration of a magnetic measuring apparatus according to an embodiment.

FIGS. 2A and 2B are diagrams showing a principle of measuring a magnetic field in the magnetic measuring apparatus.

FIG. 3 is a schematic view showing a cross-sectional structure of a gas cell.

FIG. 4 is a schematic view showing a cross-sectional structure of a gas cell according to a comparative example.

FIG. 5 is a schematic view showing a structure of the gas cell according to Structure Example 1.

FIG. 6 is a schematic view showing a structure of the gas cell according to Structure Example 2.

FIG. 7 is a schematic view showing a structure of the gas cell according to Structure Example 3.

FIG. 8 is a schematic view showing a structure of the gas cell according to Structure Example 4.

FIG. 9 is a schematic view showing a structure example of a gas cell array.

### DESCRIPTION OF EXEMPLARY EMBODIMENTS

### 1: Configuration

### 1-1. Magnetic Measuring Apparatus

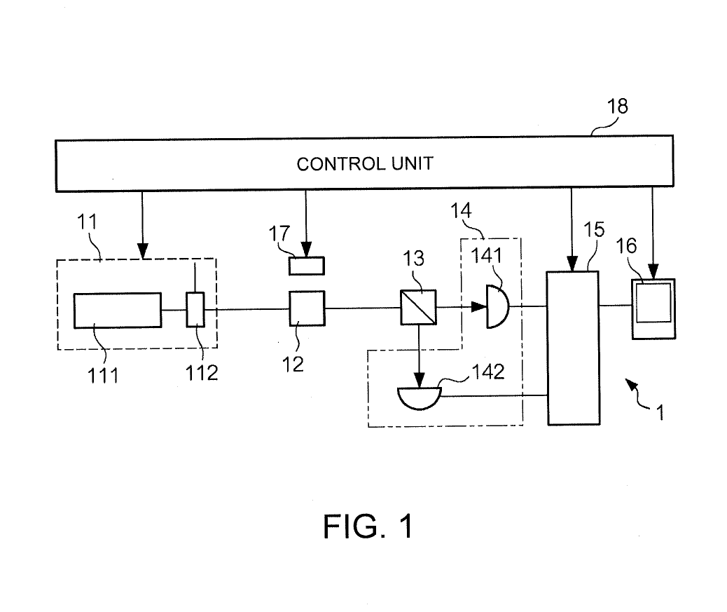

FIG. 1 is a diagram showing a configuration of a magnetic measuring apparatus 1 according to an embodiment. The magnetic measuring apparatus 1 is an apparatus that measures a magnetic field by an optical pumping method, that is, an apparatus that measures a magnetic field based on the angle of rotation of the polarization plane of probe light radiated onto alkali metal atoms that are brought into the excited state and spin polarized by pump light. In this example, the magnetic measuring apparatus 1 is a so-called one-beam type measuring apparatus in which one beam of light serves as both pump light and probe light. The magnetic measuring apparatus includes a light radiation unit 11, a gas cell 12, a polarization splitter 13, a light receiving unit 14, a signal processing unit 15, a display unit 16, a heater 17, and a control unit 18.

The light radiation unit 11 outputs light that serves as both pump light and probe light. The light radiation unit 11 includes a light source 111 and a converter 112. The light source 111 is a device that generates laser light, and includes, for example, a laser diode and a driver circuit therefor. The frequency of the laser light is a frequency corresponding to transitions between hyperfine structure levels of atoms that are enclosed in the gas cell 12 (described in detail later). The converter 112 converts the direction of linearly polarized light of the laser light output from the light source 111 into a predetermined direction. The laser light whose polarization direction has been converted by the converter 112 is radiated onto the gas cell 12 via a light guide member such as an optical fiber (not shown). The light may be radiated directly from the light radiation unit 11 onto the gas cell 12 without via the light guide member, but the use of the light guide member reduces limitations on the size, arrangement, and the like of the light radiation unit 11.

The gas cell 12 is a cell in which atoms of an alkali metal (e.g., potassium (K), cesium (Cs), etc.) are enclosed. The gas cell 12 is formed of a material that is light transmitting, does not react with the alkali metal enclosed therein, and does not transmit the alkali metal atoms, for example, silica glass, borosilicate glass, or the like. The structure of the gas cell 12 will be described in detail later. The light transmitted through the gas cell 12 is guided by the light guide member to the polarization splitter 13. The material of the gas cell 12 is not limited to glass, and any material may be used as long as the above requirements are satisfied. For example, the material may be a resin. Moreover, the light transmitted through the gas cell 12 may be directly guided to the polarization splitter 13 without via the light guide member.

The polarization splitter 13 splits the light transmitted through the gas cell 12 into polarized light in a first direction and polarized light in a second direction orthogonal to the first direction. The polarization splitter 13 is set while being rotated about a light transmitting direction by 45° so that the first direction is a direction of 45° with respect to a polarization direction after the conversion by the converter 112 and the second direction is a direction vertical to the first direction. Due to this, the light transmitted through the gas cell 12 is split such that when a magnetic field is not present in the cell, a polarization component in the first direction and a polarization component in the second direction orthogonal to the first direction are equal in level. Four ways of setting the polarization splitter 13 are conceivable depending on the angle with respect to the polarization of the light transmitted through the gas cell 12, and any set may be employed.

The light receiving unit 14 receives the polarized light in the first direction and the second direction, and outputs a signal corresponding to the amount of the received light to the signal processing unit 15. The light receiving unit 14 includes a light receiving element 141 and a light receiving element 142. The light receiving element 141 receives the polarized light in the first direction, and the light receiving element 142 receives the polarized light in the second direction. The light receiving element 141 and the light receiving element 142 both have sensitivity in the wavelength of laser light, and each generate a signal corresponding to the amount of the received light and supply the signal to the signal processing unit 15.

The signal processing unit 15 measures the magnitude of magnetic field relating to a magnetic field in a measurement axis. The angle of rotation of the polarization plane before and after the transmission through the gas cell 12 depends on a magnetic field in the gas cell 12. The signal processing unit 15 first calculates the angle of rotation of the polarization plane using the signals from the light receiving element 141 and the light receiving element 142, and then calculates the magnitude of the magnetic field from the angle of rotation. Specifically, the signal processing unit 15 takes a difference in photocurrent between the polarized light in the first direction and the polarized light in the second direction, and calculates the orientation and intensity of the magnetic field based on the difference. According to this method, the orientation of the magnetic field can also be measured. For example, the value and sign are considered as to the difference obtained by subtracting the photocurrent of the polarized light in the second direction from the photocurrent of the polarized light in the first direction. Here, when a magnetic field in the light transmitting direction is present, and when the above-described angle of the polarization splitter 13 is set such that the polarization of the light transmitted through the gas cell 12 rotates, and thus the photocurrent of the polarized light in the first direction increases and the photocurrent of the polarized light in the second direction decreases, the sign of the difference is a plus. In this set, when a magnetic field opposite to the light transmitting direction is present, the polarization of the light transmitted through the gas cell 12 rotates, the photocurrent of the polarized light in the first direction decreases, the photocurrent of the polarized light in the second direction increases, and thus the sign of the difference is a minus. In this manner, the orientation of the magnetic field can be found based on the sign of the difference. The absolute value of the difference is the magnitude of magnetic field in both cases where the sign is a plus and where the sign is a minus.

The display unit 16 displays information indicating the magnitude of the magnetic field calculated by the signal processing unit 15. The display unit 16 includes a display device such as a liquid crystal display.

The heater 17 heats the gas cell 12. The heater 17 is preferably formed of a non-magnetic material with a high thermal conductivity (e.g., ceramic, silicon carbide, or graphite). Reasons for heating the gas cell 12, which will be described in detail later, are to increase the atom density of the alkali metal in the gas cell 12 and to prevent the liquid or solid of the alkali metal from adhering to the inner wall surface of the gas cell 12.

The control unit 18 controls each part of the magnetic measuring apparatus 1. The control unit 18 includes a processor such as a CPU, and a memory. Although not shown in the drawing, the magnetic measuring apparatus 1 may further include an input device such as a keyboard or a touch screen.

### 1-2. Principle of Measurement

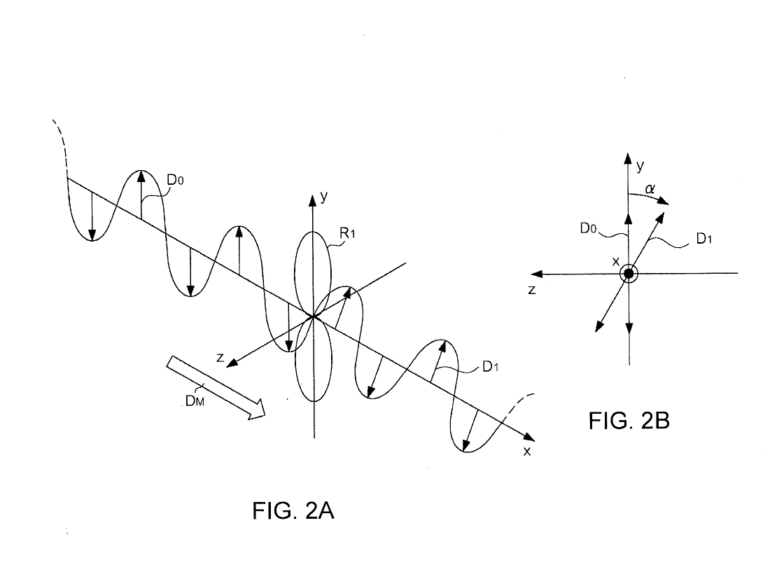

FIGS. 2A and 2B show a principle of measuring a magnetic field in the magnetic measuring apparatus 1. Herein, an example of using cesium as an alkali metal will be described. When cesium atoms enclosed in the gas cell 12 are irradiated with pump light, the cesium atoms are excited (optically pumped). This will be described in detail below. In this example, light output from the light radiation unit 11 is linearly polarized light having a wavelength to excite the hyperfine structure quantum number of cesium from the ground state F=3 to the excited state F′=4 and including an electric field that vibrates in the y-axis direction (D₀ direction). The outermost electron of cesium is excited (optically pumped) by pump light, and the angular momentum (more precisely, a spin angular momentum) of the cesium atom has a biased distribution R₁ along the electric field of the pump light. Now, since the vibration direction D₀ of the electric field of the pump light is the y-axis direction, the angular momentum is distributed to be biased mainly in the positive and negative directions of the y-axis as shown in FIG. 2A. That is, the optically pumped cesium atom has two angular momenta that are anti-parallel in the positive and negative directions of the y-axis. Herein, the anisotropy occurring in the angular momentum distribution is referred to as “alignment”, and making the anisotropic distribution occur in the angular momentum is referred to as “forming the alignment”. In other words, forming the alignment is the same as causing magnetization.

FIG. 2B shows an existing probability distribution of angular momentum in precession. Herein, an example will be described in which in a state where the alignment in the state of FIG. 2A is formed by optical pumping, a static magnetic field B is applied in the x-axis direction. The magnetic field B is, for example, a magnetic field generated from an object to be measured. By the actions of the static magnetic field B and the alignment, the cesium atom is subjected to a clockwise torque with the x-axis (the direction of the static magnetic field B) being as the axis of rotation. With this torque, the cesium atom rotates in a yz plane. This is precession. The rotation of the cesium atom means the rotation of the alignment. Herein, the angle of rotation of the alignment with an alignment in a state where no magnetic field is applied being as a reference is represented by α. When taking a look at a single atom, the bias (excited state) of the angular momentum caused by pumping decreases as time proceeds, that is, the alignment is mitigated. Since a laser beam is CW light, the formation and mitigation of the alignment are repeated simultaneously in parallel and continuously. As a result, when taking a look at the entire group of atoms, a steady (time-averaged) alignment is formed. The distribution R₁ in FIG. 2A represents the steady alignment. The angle α of rotation of the alignment and the magnitude of the angular momentum depend on the frequency (Larmor frequency) of precession and a mitigation rate determined by a plurality of factors.

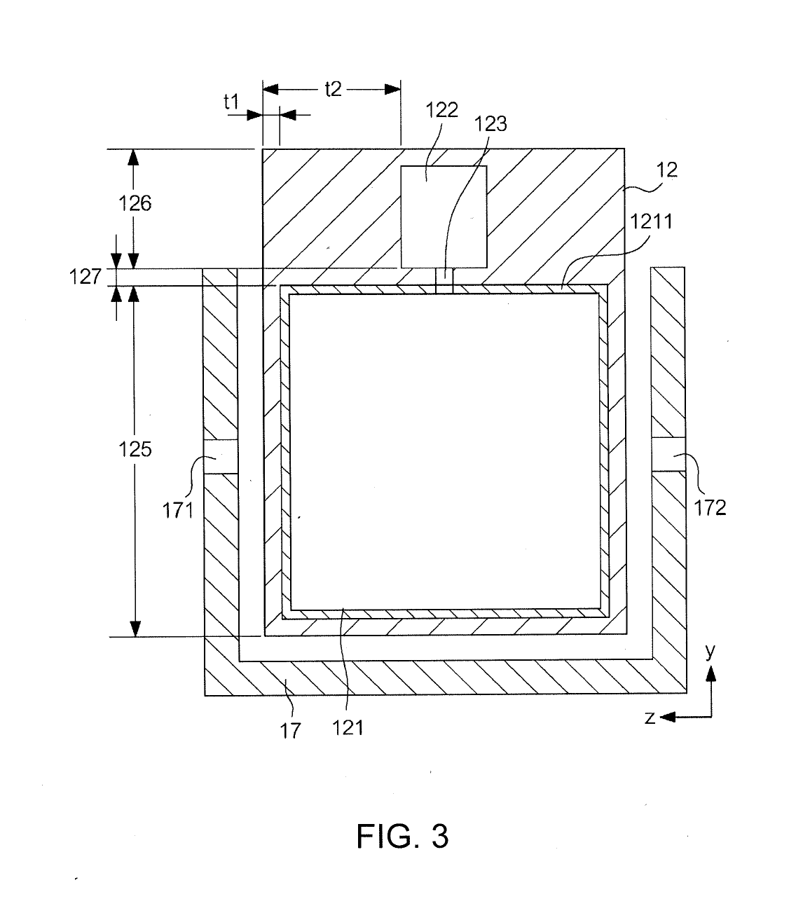

The laser beam is subjected to the action of linear dichroism due to the steady alignment. The direction of the alignment is a transmission axis, and a polarization component in this direction is mainly transmitted. A direction vertical to the direction of the alignment is an absorption axis, and a polarization component in this direction is mainly absorbed. That is, the relation t_{//}>t_{⊥} is established where T_{//}and t_{⊥} represent amplitude transmission coefficients of light in the transmission axis and the absorption axis, respectively. A transmission axis component and an absorption axis component of an electric field Eᵢ of incident light are Eᵢ cos α and Eᵢ sin α, respectively. A transmission axis component and an absorption axis component of an electric field Eₒ after transmission through the gas cell 12 (after interaction with cesium atoms) are t_{//}Eᵢ cos α and t_{⊥}Eᵢ sin α, respectively. Since the relation t_{//}>t_{⊥} is established, the electric field vector Eₒ rotates with the electric field vector Eᵢ being as a reference. That is, the polarization plane of the laser light rotates. The angle of this rotation is represented by φ. The vibration direction of the electric field after rotation is a direction D₁. In FIG. 3, the angle φ of rotation is not shown.

More precisely, a phenomenon (alignment-orientation conversion; AOC) in which the angular momentum is biased in the propagation direction of laser light occurs, and as a result, rotation (Faraday effect) of the polarization plane due to circular birefringence occurs. Herein, however, this phenomenon is ignored in description.

The laser light, which has transmitted through the gas cell 12 and whose polarization plane has been rotated, is split into two polarization components by the polarization splitter 13. In this example, the two polarization components are split into components along two axes, a first detection axis and a second detection axis. The light receiving element 141 and the light receiving element 142 detect the amounts of light components along the first detection axis and the second detection axis, respectively. When there is no rotation of the polarization plane (φ=0), the two light receiving elements show equal output values. The difference between the amounts of laser light incident on the light receiving element 141 and the light receiving element 142 is a function of the angle φ of rotation of the polarization plane. By taking the difference between the output signals of the light receiving element 141 and the light receiving element 142, information of the angle φ of rotation is obtained. The angle φ of rotation is a function of the magnetic field B (e.g., refer to Mathematical Formula (2) in D. Budker et al., “Resonant nonlinear magneto-optical effects in atoms”, Rev. Mod. Phys., 74, 1153-1201 (2002). Mathematical Formula (2) relates to linear optical rotation, but a similar formula can be used for non-linear optical rotation). That is, information of the magnetic field B can be obtained from the angle φ of rotation.

The optically pumped magnetic measuring apparatus 1 has high sensitivity, and can detect a signal at, for example, 1 pT/√Hz or less. According to the magnetic measuring apparatus 1, it is possible to measure a very feeble magnetic field originating from a living body such as the heart or the brain.

Although an example has been described herein in which the magnetic measuring apparatus 1 is an one-beam type apparatus, the magnetic measuring apparatus may be a two-beam type apparatus, that is, an apparatus of a type in which pump light and probe light are separate laser lights.

### 1-3. Structure of Gas Cell

FIG. 3 is a schematic view showing a cross-sectional structure of the gas cell 12. This cross-section is parallel to the yz plane. That is, laser light travels from the left to the right of the drawing. The main body of the gas cell 12 is formed of a material that is light transmitting, does not react with an alkali metal enclosed therein, and does not transmit alkali metal atoms, for example, silica glass, borosilicate glass, or the like. The gas cell 12 includes a main chamber 121 (also referred to as a “first chamber”) and an auxiliary chamber 122 (also referred to as a “second chamber”) that are an interior space defined by the inner wall of the main body.

The general structure of the gas cell 12 will be described below. The main chamber (first chamber) 121 is a space to be filled with the alkali metal in the gaseous state (hereinafter referred to as “alkali metal gas”). The auxiliary chamber (second chamber) 122 is a space to store the alkali metal in the solid or liquid state. The main chamber 121 and the auxiliary chamber 122 are in communication with each other. In manufacture of the gas cell 12, the alkali metal in the solid state is inserted into the auxiliary chamber 122. The interior space (the main chamber 121 and the auxiliary chamber 122) of the gas cell 12 is sealed under reduced pressure. In use of the magnetic measuring apparatus 1, that is, in use of the gas cell 12, the gas cell 12 is heated. When the gas cell 12 is heated, the alkali metal in the liquid or solid state in the auxiliary chamber 122 is vaporized and converted into the alkali metal gas. The alkali metal gas diffuses from the auxiliary chamber 122 into the main chamber 121, so that the main chamber 121 is filled with the alkali metal gas. When the use of the magnetic measuring apparatus 1 is stopped, the heating of the gas cell 12 is stopped. When the heating is stopped, the gas cell 12 is cooled. At this time, the alkali metal gas present in the interior space (the main chamber 121 and the auxiliary chamber 122) is liquefied or solidified, and adheres to the inner wall surface. From the viewpoint of reducing adverse effects on measurement, it is desirable that the alkali metal in the liquid or solid state does not adhere to the inner wall of the main chamber 121 in heating and cooling of the gas cell 12, that is, in use and not in use of the magnetic measuring apparatus 1. That is, it is desirable that the alkali metal in the liquid or solid state adheres not to the inner wall of the main chamber 121 but to the inner wall of the auxiliary chamber 122. To cause the alkali metal in the liquid or solid state to adhere not to the inner wall of the main chamber 121 but to the inner wall of the auxiliary chamber 122, the temperature of the auxiliary chamber 122 is desirably lower than that of the main chamber 121. Hereinafter, the structure of the gas cell 12 for making the temperature of the auxiliary chamber 122 lower than that of the main chamber 121 will be described in detail.

The main chamber (first chamber) 121 is a space for the gas cell 12 to exert a function as a sensing element, that is, a space in which the alkali metal gas is enclosed. The auxiliary chamber (second chamber) 122 is a space that functions as an alkali metal reservoir. The alkali metal gas enclosed in the main chamber 121 is solidified at a low temperature. At this time, if the solidified alkali metal adheres to the wall surface of the main chamber 121, the solidified alkali metal is obstructive to pump light or probe light and thus interferes with measurement. The alkali metal reservoir, that is, the auxiliary chamber 122 is a space to store the alkali metal so as not to interfere with measurement, that is, a space serving as a supply source of the alkali metal. In the drawing, the auxiliary chamber 122 is illustrated in an enlarged manner. However, for reducing influences on the pressure of the main chamber, the auxiliary chamber 122 is preferably sufficiently smaller than the main chamber 121 (e.g., the volume is 1/100 or less).

A coating layer 1211 is formed on at least a portion of the inner wall of the main chamber 121. The coating layer 1211 is provided for purposes of preventing the mitigation of spin polarization. The coating layer 1211 is formed of hydrocarbon having a linear molecular structure, for example, paraffin.

The main chamber 121 and the auxiliary chamber 122 are coupled together by means of a vent hole 123. To make a pressure distribution in the main chamber 121 close to being constant, the diameter and length of the vent hole 123 are preferably smaller than, for example, the mean free path of the alkali metal gas.

The main chamber 121 and the auxiliary chamber 122 both have a rectangular parallelepiped shape except for a portion connected with the vent hole 123. As one example, the main chamber 121 is a cube of 2 cm×2 cm×2 cm. The inner circumference of the vent hole 123 is a circle with a diameter of 0.5 mm. The auxiliary chamber 122 is a rectangular parallelepiped of 1 mm×1 mm×5 mm.

The gas cell 12 has a rectangular parallelepiped shape as a whole. That is, in the wall surface constituting the gas cell 12, a portion defining the main chamber 121 (hereinafter referred to as a wall portion 125) and a portion defining the auxiliary chamber 122 (hereinafter referred to as a wall portion 126) are different in thickness (wall thickness). In the example of FIG. 3, the thickness of the wall portion 125 is t1, and the thickness of the wall portion 126 is t2. The wall portion 126 is thicker than the wall portion 125, that is, the relation t2>t1 is established. In the wall surface constituting the gas cell 12, a portion defining the vent hole 123 is referred to as a wall portion 127.

In the gas cell 12, a portion composed of the wall portion 125 and the wall portion 127 is referred to as the “cell main body”. In the example of FIG. 3, the external appearance of the gas cell 12 is a rectangular parallelepiped, and the cell main body and the wall portion 126 are integrated. The term “integrated” as used herein is used to include not only a portion formed of a single member but also a portion integrated by bonding separate members together.

In the wall surface defining the main chamber 121, the wall portion 125 is a portion excepting a portion interposed between the main chamber 121 and the auxiliary chamber 122, that is, the wall portion 125 is the wall surface excepting the upper surface portion of the main chamber 121 in this example. Similarly, in the wall surface defining the auxiliary chamber 122, the wall portion 126 is a portion excepting a portion interposed between the main chamber 121 and the auxiliary chamber 122, that is, the wall portion 126 is the wall surface excepting the lower surface portion of the auxiliary chamber 122 in this example.

The thickness of the wall portion 125 is uniform in the example of FIG. 3, but the thickness of the wall portion 125 may not be uniform. For example, a portion of the wall portion 125, which corresponds to the lower surface of the main chamber 121, may be thicker than the side surface thereof. When the thickness of the wall portion 125 is not uniform as described above, the thickness of the wall portion 125 means the average value of the thicknesses of the wall portion 125. The same applies to the wall portion 126.

In manufacture of the gas cell 12, the alkali metal in the form of paste or solid is introduced into the auxiliary chamber 122. The sensitivity of the magnetic measuring apparatus 1 depends on the atom density of the alkali metal gas in the main chamber 121, that is, a vapor pressure. As the atom density of the alkali metal gas in the main chamber 121 increases, measurement sensitivity increases. For increasing the atom density of the alkali metal gas in the main chamber 121, the gas cell 12 is heated by the heater 17. The solid or liquid alkali metal in the auxiliary chamber 122 is vaporized by heating, so that the atom density of the alkali metal gas in the main chamber 121 increases.

It is sufficient that the atom density of the alkali metal gas in the main chamber 121 is increased to a desired density when an actual measurement is performed, and therefore, the gas cell 12 is heated by the heater 17 only in measurement. When the apparatus is stopped, the heating using the heater 17 is also stopped. Since the temperature of the gas cell 12 is lowered when the heating using the heater 17 is stopped, a portion of the alkali metal gas is liquefied or solidified. At this time, the liquefied or solidified alkali metal is ideally stored in the auxiliary chamber 122, but the liquefied or solidified alkali metal adheres in some cases to the wall surface of the main chamber 121. When the alkali metal adheres to the wall surface of the main chamber 121, the alkali metal may remain adhering to the wall surface of the main chamber 121 in the next measurement. If the place where the alkali metal adheres is located on the optical path of laser light, the laser light is blocked and measurement is adversely affected. Hence, it is desirable that the liquefied or solidified alkali metal is prevented from adhering to the wall surface of the main chamber 121, that is, the liquefied or solidified alkali metal is caused to be stored in the auxiliary chamber 122.

For causing the liquefied or solidified alkali metal to be stored in the auxiliary chamber 122, the temperature of the auxiliary chamber 122 is made lower than that of the main chamber 121. From the viewpoint of this, the heater 17 is disposed so as to surround the main chamber 121 and is not disposed around the auxiliary chamber 122. That is, the heater 17 is disposed around the periphery of the wall portion 125 and is not disposed around the periphery of the wall portion 126.

The heater 17 includes an opening 171 and an opening 172 to allow the laser light to transmit therethrough. Moreover, the positional relationship between the heater 17, and the main chamber 121 and the auxiliary chamber 122 is not limited to the example of FIG. 3. For example, the heater 17 may extend to a portion of the periphery of the wall portion 126.

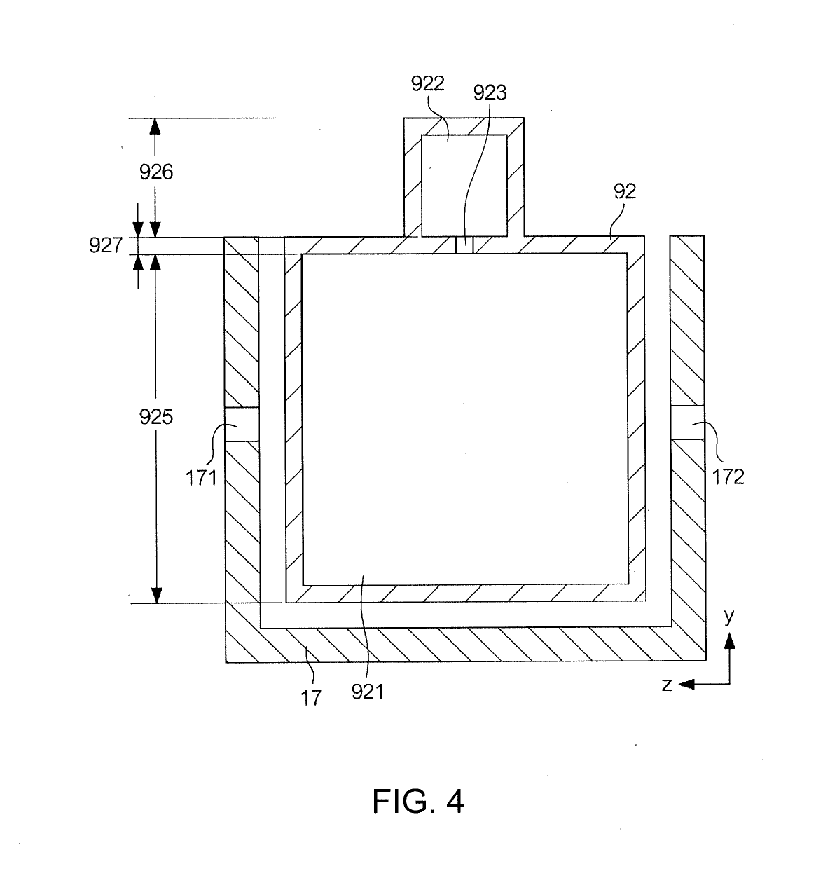

FIG. 4 is a schematic view showing a cross-sectional structure of a gas cell 92 according to a comparative example. The gas cell 92 includes a main chamber 921, an auxiliary chamber 922, and a vent hole 923. Also in this drawing, the auxiliary chamber 922 is illustrated in an enlarged manner similarly to FIG. 3. The main chamber 921 is defined by a wall portion 925, the auxiliary chamber 922 is defined by a wall portion 926, and the vent hole 923 is defined by a wall portion 927. The heater 17 is disposed around the peripheries of the wall portion 125 and the wall portion 127. In this example, the thicknesses of the wall portion 925 and the wall portion 926 are substantially the same as each other. Compared to the structure of FIG. 3, the volume of the wall portion 926 is smaller than that of the wall portion 126. When it is assumed that the wall portion 926 and the wall portion 126 are formed of the same material and the auxiliary chamber 922 and the auxiliary chamber 122 have the same volume, the heat capacity of the wall portion 926 is smaller than that of the wall portion 126, and therefore, the temperature increases more in the wall portion 926 than in the wall portion 126. That is, the situation is such that the temperatures of the main chamber 921 and the auxiliary chamber 922 hardly differ from each other.

That the temperatures of the main chamber 921 and the auxiliary chamber 922 hardly differ from each other means that the alkali metal is hardly stored in the auxiliary chamber 922, that is, the alkali metal easily adheres to the wall surface of the main chamber 921. That is, the previously described problem easily occurs.

In contrast, in the gas cell 12, the wall portion 126 is thick (i.e., the wall portion of the auxiliary chamber is large) compared to the configuration of FIG. 4. This means that the heat dissipating property of the wall portion 126 is enhanced, that is, the wall portion 126 functions as a heat dissipating portion. Hence, the temperatures of the main chamber 121 and the auxiliary chamber 122 easily differ from each other, that is, the situation is such that the temperature of the auxiliary chamber 122 is easily lower than that of the main chamber 121. That the temperature of the auxiliary chamber 122 is lowered means that the alkali metal is easily stored in the auxiliary chamber 122, that is, the alkali metal hardly adheres to the wall surface of the main chamber 121. That is, the previously described problem hardly occurs.

### 1-4. Structure Example of Gas Cell

In the viewpoint of enhancing the heat dissipation effect of the auxiliary chamber compared to the example of FIG. 4, the structure of the gas cell 12 is not limited to that illustrated in FIG. 3. Hereinafter, some specific structures of the gas cell 12 will be illustrated. In the drawings described below, the main chamber and the auxiliary chamber are shown by dashed lines.

### 1-4-1. Structure Example 1

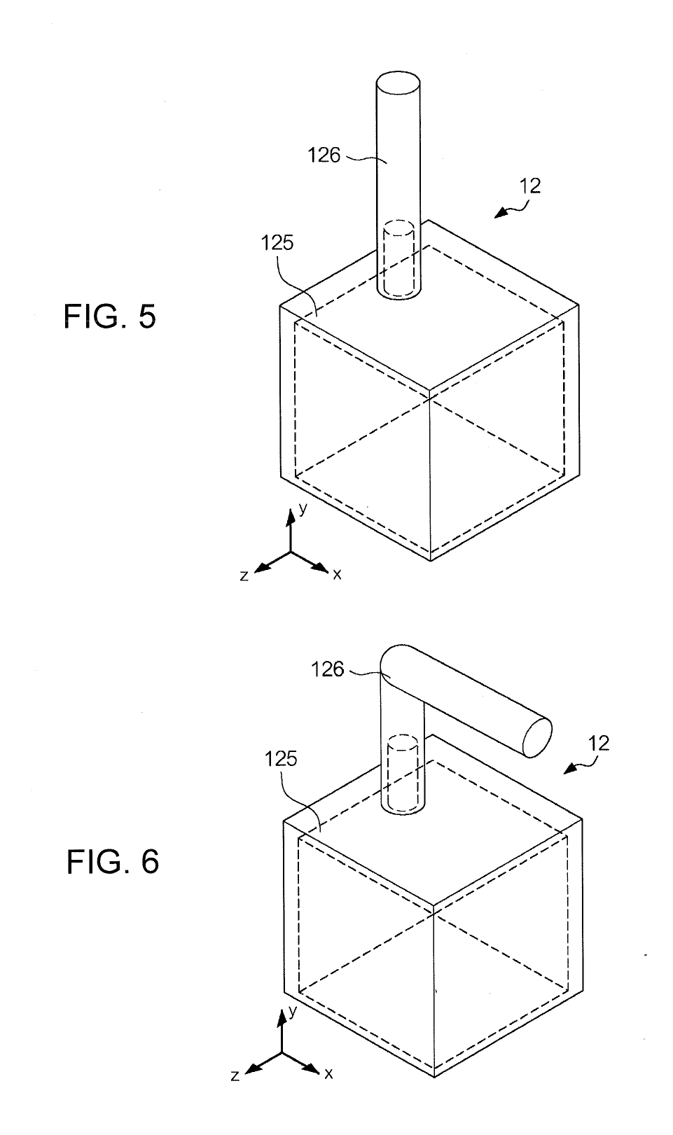

FIG. 5 is a schematic view (perspective view) showing a structure of the gas cell 12 according to Structure Example 1. In this example, the thickness of the wall portion 126 in the side direction (z-direction) is substantially the same as that of the wall portion 125, but the thickness of the wall portion 126 in the height direction (y-direction) is thicker than that of the wall portion 125. That is, the gas cell 12 is not a rectangular parallelepiped but has a shape in which a long protruding portion corresponding to the auxiliary chamber 122 is formed on a rectangular parallelepiped (cube) corresponding to the main chamber 121 (i.e., a shape in which the protruding portion is formed on the cell main body). Also in this drawing, the protruding portion (the wall portion 126 defining the auxiliary chamber 122) is illustrated in an enlarged manner. Moreover, in this example, the protruding portion (the wall portion 126) is formed not at the center of the upper surface of the cell main body but at a position shifted from the center.

### 1-4-2. Structure Example 2

FIG. 6 is a schematic view showing a structure of the gas cell 12 according to Structure Example 2. In the example of FIG. 5, the protruding portion corresponding to the auxiliary chamber 122 extends straight in the height direction; while, in this example, a protruding portion is bent in the lateral direction (z-direction) in the middle. According to this example, compared to the structure of FIG. 5, the size in the vertical direction can be reduced.

### 1-4-3. Structure Example 3

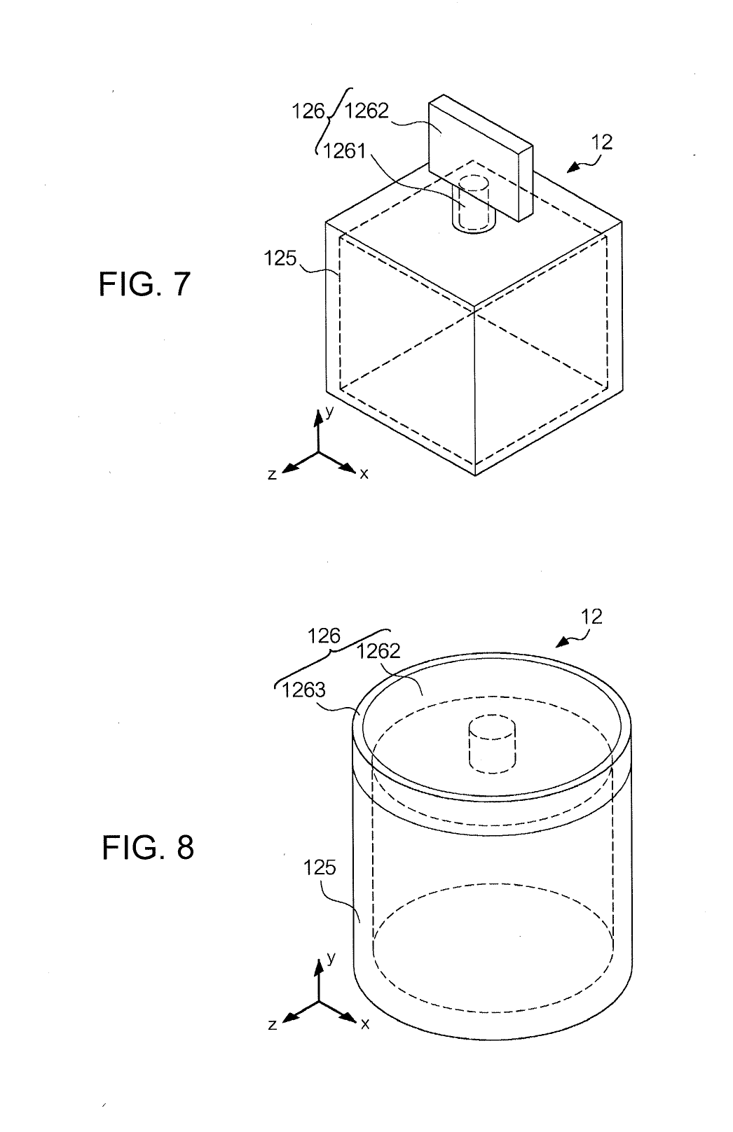

FIG. 7 is a schematic view showing a structure of the gas cell 12 according to Structure Example 3. In this example, the wall portion 126 includes a protruding portion 1162 and a heat dissipating portion 1162. The protruding portion 1161 is formed of the same material (e.g., glass) as the wall portion 125. The heat dissipating portion 1162 is formed of a material with a higher thermal conductivity (e.g., a metal such as aluminum, gold, silver, or copper) than that of the protruding portion 1161. Even when the protruding portion 1161 itself is formed of a material with the same thickness as that of the wall portion 125, heat dissipation efficiency is enhanced as the entire wall portion 126 due to the heat dissipating portion 1162. The heat dissipating portion 1162 preferably has a shape with a larger surface area from the viewpoint of enhancing the heat dissipating property. For example, the heat dissipating portion 1162 is preferably provided with surface irregularities thereon, or provided with a hole. Moreover, the ratio of a surface area S2 of the entire wall portion 126 to a volume V2 of the auxiliary chamber 122 is preferably greater than the ratio of a surface area of the wall portion 125 to a volume V1 of the main chamber 121. That is, the relation (S2/V2)>(S1/V1) is preferably established.

### 1-4-4. Structure Example 4

FIG. 8 is a schematic view showing a structure of the gas cell 12 according to Structure Example 4. In this example, the wall portion 126 includes an inner wall portion 1263 and an outer wall portion 1264. The inner wall portion 1263 is formed of the same material (e.g., glass) as the wall portion 125. The outer wall portion 1264 is formed of a material with a higher thermal conductivity (e.g., a metal) than that of the inner wall portion 1263. The outer wall portion 1264 is formed on the outer circumference of the inner wall portion 1263. That is, this example has a structure in which a metal foil is wrapped around the wall portion of the auxiliary chamber 122 in the structure of FIG. 3. The metal foil is bonded to the outer circumferential surface of the inner wall portion using, for example, a silicone resin adhesive. In this example, the shape of the cell main body is not a rectangular parallelepiped but a circular cylinder. The outer wall portion 1264 is formed only on the outer circumference of the inner wall portion 1263 in the lateral direction. That is, the metal foil is wrapped around only the side surface of the auxiliary chamber 122, and the metal foil is not bonded to the upper surface. However, the metal foil may be bonded to a portion of the inner wall portion 1263, which corresponds to the upper surface of the auxiliary chamber 122.

### 2. Modified Example

The invention is not limited to the embodiment described above, but various modifications can be implemented. Hereinafter, some modified examples will be described. Two or more of the modified examples described below may be used in combination with each other.

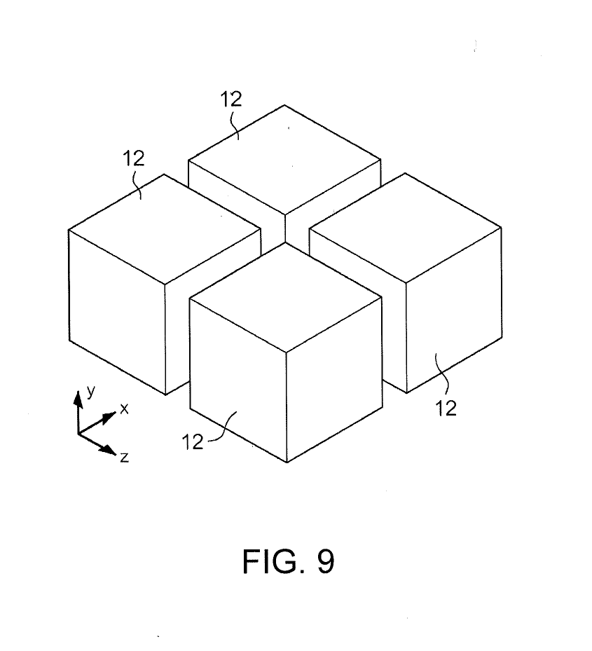

FIG. 9 is a diagram showing a structure example of a gas cell array. In the embodiment described above, the structure of a single gas cell 12 has been described. However, a plurality of gas cells 12 may be disposed one-dimensionally or two-dimensionally and used as a gas cell array. In this case, when the orientations of the auxiliary chambers 122 in all of the gas cells 12 constituting the gas cell array are aligned in the same direction, it is sufficient to cool one specific surface of the gas cell array, and therefore, the gas cells 12 can be efficiently heated and cooled.

The shape of the gas cell 12 or the shape of the main chamber 121 is not limited to a rectangular parallelepiped. The gas cell 12 or the main chamber 121 may have, for example, a circular cylinder shape, a prism (triangular prism, quadratic prism, hexagonal prism, etc.) shape, or a spherical shape.

The coating layer 1211 may be omitted. That is, the inner wall surface of the main chamber 121 may be glass.

The uses of the gas cell 12 are not limited to the magnetic measuring apparatus. The gas cell 12 may be used for apparatuses other than the magnetic measuring apparatus, such as an atomic oscillator.

The entire disclosure of Japanese Patent Applications No. 2014-150717, filed Jul. 24, 2014 and No. 2015-101620 filed May 19, 2015 are expressly incorporated by reference herein.

What is claimed is:

1. A gas cell comprising:
a first chamber having an interior space defined by a first surface of a first wall portion;
a second chamber defined by a first surface of a second wall portion and connected with the first chamber; and
a heater provided along a second surface of the first wall portion, the second surface being different from the first surface, wherein
a distance between the first surface of the second wall portion and a second surface thereof different from the first surface is greater than a distance between the first and second surfaces of the first wall portion.

2. The gas cell according to claim 1, wherein
a heat capacity of the second wall portion is greater than a heat capacity of the first wall portion.

3. The gas cell according to claim 1, wherein
the second wall portion includes
a first portion formed of the same structure material as the first wall portion, and
a second portion provided on at least a portion of an outer surface of the first portion and formed of a metal.

4. The gas cell according to claim 1, wherein
a ratio of a surface area of the first surface of the second wall portion to a volume of the second chamber is greater than a ratio of a surface area of the first surface of the first wall portion to a volume of the first chamber.

5. A gas cell comprising:
a cell main body;
a first wall portion defining an interior space serving as a main chamber in the cell main body;
an auxiliary chamber storing an alkali metal;
a second wall portion defining the auxiliary chamber connected with the main chamber in the cell main body; and
a heater covering the first wall portion and vaporizing the alkali metal, wherein
the second wall portion is thicker than the first wall portion.

6. The gas cell according to claim 5, wherein
a heat capacity of the second wall portion is higher than a heat capacity of the first wall portion.

7. The gas cell according to claim 5, wherein
the second wall portion includes
a first portion formed of the same structure material as the first wall portion, and
a second portion provided on at least a portion of an outer surface of the first portion and formed of a metal.

8. The gas cell according to claim 5, wherein
a ratio of a surface area of the second wall portion to a volume of the auxiliary chamber is greater than a ratio of a surface area of the first wall portion to a volume of the main chamber.

9. A magnetic measuring apparatus comprising:
the gas cell according to claim 1;
a light source emitting light onto the gas cell; and
a detector detecting the light passed through the gas cell, wherein
the vaporized alkali metal changes the orientation of a polarization plane of the light in response to a magnetic field strength.

10. A magnetic measuring apparatus comprising:
the gas cell according to claim 5;
a light source emitting light onto the gas cell; and
a detector detecting the light passed through the gas cell, wherein
the vaporized alkali metal changes the orientation of a polarization plane of the light in response to a magnetic field strength.
